(19) United States
(12) Patent Application Publication
(10) Pub. No.: US 2023/0029438 A1
(43) Pub. Date: Jan. 26, 2023

(54) SEMICONDUCTOR DEVICE

(71) Applicant: RENESAS ELECTRONICS CORPORATION, Tokyo (JP)

(72) Inventors: Yasutaka NAKASHIBA, Tokyo (JP); Masami SAWADA, Tokyo (JP)

(21) Appl. No.: 17/828,349

(22) Filed: May 31, 2022

(30) Foreign Application Priority Data
Jul. 20, 2021 (JP) 2021-119542

(51) Int. Cl. H01L 29/78; H01L 29/06; H01L 29/66

(52) U.S. Cl. CPC H01L 29/7813; H01L 29/0634; H01L 29/66734

(57) ABSTRACT

Reliability of a semiconductor device is improved by suppressing occurrence of variation in characteristics of the semiconductor device provided with a power MOSFET that has a super junction structure. A fixed charge layer FC is formed in a trench T2 that is formed in an upper surface of a semiconductor substrate SB and is adjacent to a p type body region BD and an n type drift layer DL. The fixed charge layer FC constituting a p column accumulates holes in the semiconductor substrate SB located at a side surface of the trench T2 to form a hole accumulation region HC.

### CROSS-REFERENCE TO RELATED APPLICATIONS

The disclosure of Japanese Patent Application No. 2021-119542 filed on Jul. 20, 2021 including the specification, drawings and abstract is incorporated herein by reference in its entirety.

### BACKGROUND

The present invention relates to a semiconductor device, and the present invention relates to an effective technique to be applied to a semiconductor device provided with a vertical field effect transistor that has a fixed charge layer in the vicinity of a side surface of a trench formed in an upper surface of a semiconductor substrate, for example.

A super junction structure is known as a structure of a power MOSFET (Metal Oxide Semiconductor Field Effect Transistor). The super junction structure is a structure in which a gate electrode in a trench formed in an upper surface of a semiconductor substrate, an n type layer in the semiconductor substrate under the trench, and the n type layer are sandwiched by a p type layer. As a method of forming the p type layer, a method of forming a p type layer by forming a trench in an upper surface of a semiconductor substrate and then introducing p type impurities into a side surface of the trench by an oblique ion implantation method is known.

Patent Document 1 (Japanese Unexamined Patent Application Publication No. 2017-143188) describes a semiconductor device that includes an insulated gate type field effect transistor unit having a super junction structure and a snubber portion.

There are disclosed techniques listed below. [Patent Document 1] Japanese Unexamined Patent Application Publication No. 2017-143188

### SUMMARY

Generally, a trench formed in an upper surface of a semiconductor substrate is formed by using dry etching. For this reason, it is difficult to stably form a side surface thereof with respect to the upper surface. The trench has an angle (trench angle) with respect to the upper surface, and a width of an upper end of the trench is generally wider than that of a lower end thereof. In a case where the trench angle varies depending upon manufacturing variation and a plurality of p type layers is formed by the oblique ion implantation method as described above, the amount of impurities injected to the p type layers varies due to the variation in the trench angles. For this reason, there is a problem that it is difficult to stabilize the variation in the characteristics (withstand voltage) of the power MOSFET.

The other object and new feature will become apparent from description of the present specification and the accompanying drawings.

An outline of representative one of embodiment disclosed in the present application will briefly be explained as follows.

A semiconductor device according to one embodiment is one in which a fixed charge layer is formed in a trench that is formed in an upper surface of a semiconductor substrate and is adjacent to a p type body region and an n type drift layer. The fixed charge layer constituting a p column accumulates holes in the semiconductor substrate located at a side surface of the trench to form a hole accumulation region.

According to one embodiment, it is possible to improve reliability of a semiconductor device.

### BRIEF DESCRIPTION OF THE DRAWINGS

FIG. 1 is a sectional view illustrating a semiconductor device according to a first embodiment.

FIG. 2 is a sectional view illustrating a semiconductor device according to a second embodiment.

FIG. 3 is a sectional view illustrating a semiconductor device according to a third embodiment.

FIG. 4 is a sectional view illustrating a semiconductor device according to a comparative example.

### DETAILED DESCRIPTION

In embodiments described below, the invention will be described in a plurality of sections or embodiments when required as a matter of convenience. However, these sections or embodiments are not irrelevant to each other unless otherwise stated, and the one relates to the entire or a part of the other as a modification example, details, or a supplementary explanation thereof. Further, in the embodiments described below, in a case of referring to the number of elements (including number of pieces, values, amount, range, and the like), the number of the elements is not limited to a mentioned number unless otherwise stated or except the case where the number is apparently limited to a specific number in principle, and the number larger or smaller than the mentioned number may also be applicable.

Moreover, in the embodiments described below, it goes without saying that the components (including element steps and the like) are not always indispensable unless otherwise stated or except the case where the components are apparently indispensable in principle. Similarly, in the embodiments described below, when the shape of the components, positional relation thereof, and the like are mentioned, the substantially approximate and similar shapes and the like are included therein unless otherwise stated or except the case where it is conceivable that they are apparently excluded in principle. The same goes for the numerical value and the range described above.

Hereinafter, the embodiments will be described in detail with reference to the drawings. Note that in all of the drawings for explaining the embodiments, the same reference numeral is assigned to a member having the same function, and repeated explanation thereof will be omitted. Further, in the following embodiments, in principle, explanation of the same or similar will not be repeated unless otherwise necessary.

Further, “−” and “+” are codes that indicate relative impurity concentrations of an n type or p type conductive type. For example, the concentration of n type impurities increases in the order of “n−−”, “n−”, “n”, “n+”, and “n++”.

### First Embodiment

<Structure of Semiconductor Device>

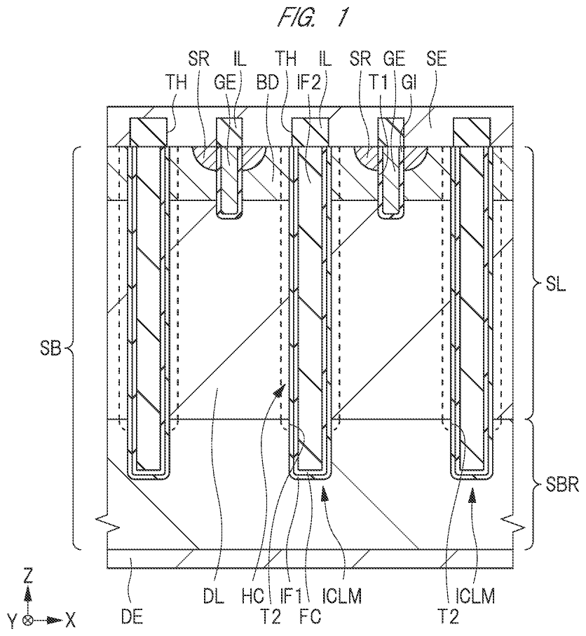

Hereinafter, a structure of a semiconductor device according to a first embodiment will be described with reference to FIG. 1. The semiconductor device according to the present embodiment includes a vertical power MOSFET (MOS type field effect transistor) having a super junction structure.

As illustrated in FIG. 1, the semiconductor device according to the present embodiment has a semiconductor substrate SB. The semiconductor substrate SB has an upper surface (a first principal surface) and a lower surface (a second principal surface) facing each other. Each of the upper surface and the lower surface of the semiconductor substrate SB extends along an X direction and a Y direction orthogonal to each other. A normal direction of the upper surface of the semiconductor substrate SB is a Z direction. The semiconductor substrate SB includes a substrate region SBR, and a semiconductor layer SL on the substrate region SBR. In this case, an upper surface of the semiconductor layer SL constitutes the upper surface of the semiconductor substrate SB, and a lower surface of the substrate region SBR constitutes the lower surface of the semiconductor substrate SB.

The substrate region SBR is composed of an n type semiconductor. The substrate region SBR has an electrical resistivity of 5 mΩ·cm or less, for example. The substrate region SBR is composed of n+ type monocrystalline silicon, for example. The semiconductor layer SL has a drift layer DL, which is mainly a n type semiconductor region, and contains n type impurities. A thickness of the semiconductor layer SL is determined in accordance with withstand pressure of the power MOSFET. The substrate region SBR has a relatively lower electrical resistivity than that of the semiconductor layer SL. The concentration of the n type impurities in the substrate region SBR is relatively higher than the concentration of the n type impurities in the semiconductor layer SL.

The power MOSFET according to the present embodiment includes the n type drift layer DL, a p type body region BD, an n type source region SR, a gate insulating film GI, a gate electrode GE, and a source electrode SE. Namely, the power MOSFET is an n type field effect transistor. Further, the substrate region SBR constitutes a drain region of the power MOSFET. The power MOSFET further includes a drain electrode DE, an insulator column ICLM, and an interlayer insulating film IL. The gate electrode GE is formed in a trench T1 formed in the upper surface of the semiconductor substrate SB via the gate insulating film GI. The insulator column ICLM includes an insulating film in the trench T2 formed in the upper surface of the semiconductor substrate SB.

The n type drift layer DL is arranged in the semiconductor substrate SB. The drift layer DL arranged on the substrate region SBR. The drift layer DL has lower concentration of the n type impurities than that of the substrate region SBR. The drift layer DL has a higher electrical resistivity than that of the substrate region SBR. The drift layer DL is an n− type silicon layer, for example.

The body region BD, which is a p type semiconductor region, is arranged on the drift layer DL in the semiconductor substrate SB. The body region BD is a p type silicon layer, for example.

The source region SR, which is an n type semiconductor region, is arranged on the body region BD in the semiconductor substrate SB. Specifically, the source region SR is formed in contact with the trench T1 from the upper surface of the semiconductor layer SL to an intermediate depth of the semiconductor layer SL. The n type source region SR has higher concentration of the n type impurities than that of the drift layer DL. The source region SR has a lower electrical resistivity than that of the drift layer DL. The source region SR is discretely arranged along the X direction in the upper surface of the semiconductor substrate SB. The source region SR extends along the Y direction. The source region SR is an n+ type silicon region, for example.

The trench T1 is a relatively shallow groove formed in the upper surface of the semiconductor layer SL. The trench T1 is formed at a position sandwiched between the two adjacent source regions SR arranged in the X direction, and is in contact with these source regions SR. On the other hand, the trench T2 is a relatively deep groove formed in the upper surface of the semiconductor layer SL. The trench T2 is separated from each of the two source regions SR respectively adjacent to the trenches T1 via the corresponding body region BD. The trenches T1 and the trenches T2 are formed alternately side by side in the X direction. Each of the adjacent trenches T1 and T2 in the X direction is in contact with one body region BD formed between them. A bottom of the trench T1 is terminated at an intermediate depth of the drift layer DL below the body region BD, and does not reach the substrate region SBR. On the other hand, a bottom of the trench T2 reaches an intermediate depth of the substrate region SBR. However, the bottom of the trench T2 may be terminated in the drift layer DL, and may not reach the substrate region SBR.

The trench T2 illustrated in FIG. 1 appears to have a vertical side surface along the Z direction, but in actual, a side surface of the trench T2 is formed diagonally with respect to the Z direction, and has a trench angle. A width of the trench T2 in the X direction (short direction) gradually increases from a bottom surface of the trench T2 toward an upper end side of the trench T2. Note that a side surface of the trench T1 also has a trench angle.

The gate insulating film GI continuously covers the side surface and a bottom surface of the trench T1. A portion of the body region BD sandwiched between the drift layer DL and the source region SR and adjacent to the trench T1 is a portion where a channel is formed in an ON state of the power MOSFET. The gate insulating film GI is arranged on the portion of the body region BD sandwiched between the drift layer DL and the source region SR. The trench T1 is arranged over the body region BD and the n type drift layer DL. The gate insulating film GI is in contact with the p type body region BD and the n type drift layer DL. The gate insulating film GI is a silicon oxide film, for example.

The gate electrode GE is arranged so as to face the portion of the body region BD sandwiched between the drift layer DL and the source region SR via the gate insulating film GI. Namely, the gate electrode GE is formed in the trench T1 via the gate insulating film GI. The gate electrode GE is a trench gate type the gate electrode GE. Note that the gate electrode GE may be a planar type gate electrode GE formed on the semiconductor layer SL instead of the trench gate type. The gate electrodes GE are arranged discretely along the X direction. Each of the gate electrodes GE extends along the Y direction. A height of the gate electrode GE in the Z direction is larger than a depth of the body region BD in the Z direction. The gate electrode GE is a polycrystalline silicon film, for example. The gate electrode GE is electrically connected to a gate wiring via a contact hole (not illustrated in the drawings).

The insulator column ICLM is arranged in the trench T2. The insulator column ICLM is arranged in the drift layer DL, the body region BD, and the substrate region SBR. The insulator column ICLM is arranged on the upper surface side of the semiconductor substrate SB. The insulator column ICLM is arranged in the trench T2 formed over the insides of the drift layer DL, the body region BD, and the substrate region SBR. An insulating film IF1, a fixed charge layer FC, and an insulating film IF2 are embedded in the trench T2 in this order. In other words, the side surface and the bottom surface of the trench T2 are continuously covered with the insulating film IF1, and a fixed charge layer FC is formed in the trench T2 via the insulating film IF1. Further, the insulating film IF2 is completely embedded in the trench T2 via a laminated film composed of the insulating film IF1 and the fixed charge layer FC. Namely, the trench T2 is filled with the insulating film IF2 via the laminated film.

The fixed charge layer FC is an insulating film. Namely, the insulator column ICLM is filled with a laminated insulating film composed of the insulating films IF1 and IF2 and the fixed charge layer FC. The fixed charge layer FC is adjacent to the body region BD and the drift layer DL in the X direction.

The fixed charge layer FC is a hole accumulation layer made of a material that accumulates holes, and is composed of a high-k film that contains Hf (hafnium), for example. As the material constituting the fixed charge layer FC, HfOx (hafnium oxide) or hafnium oxynitride is cited. In this case, a specific material constituting the fixed charge layer FC is HfSiO (hafnium silicate), HfSiON (nitrogen-added hafnium silicate), or HfAlON (nitrogen-added hafnium aluminate), for example. In addition, the high-k film constituting the fixed charge layer FC may be made of yttrium oxide or aluminum oxide. Namely, the fixed charge layer FC may be made of Y₂O₃ (yttrium oxide) or Al₂O₃ (aluminum oxide). Each of the insulating films IF1 and IF2 is a silicon oxide film, for example. Namely, the material constituting the fixed charge layer FC is at least one kind selected from a group consisting of hafnium oxide, hafnium oxynitride, yttrium oxide, and aluminum oxide.

The insulator column ICLM is arranged between the adjacent gate electrodes GE in a plan view from the Z direction. A plurality of the insulator columns ICLM is formed, and the adjacent insulator columns ICLM are arranged so as to sandwich the gate electrode GE in the plan view from the Z direction. The plurality of insulator columns ICLM is arranged discretely in the X direction. Each of the plurality of insulator columns ICLM extends along the Y direction.

By forming the fixed charge layer FC made by the high-k film in the trench T2, a hole accumulation region HC is generated in the semiconductor layer SL in the vicinity of the side surface of the trench T2. Namely, the hole accumulation region HC is formed on the side surface of the trench T2 adjacent to the fixed charge layer FC. FIG. 1 illustrates the hole accumulation region HC by a broken line. The hole accumulation region HC is a region where holes are accumulated. Namely, the holes in the surrounding semiconductor layer SL are gathered in the semiconductor layer SL in the vicinity of the side surface of the trench T2 due to a Fermi pinning effect of the fixed charge layer FC made by the high-k film. The insulator column ICLM that causes the hole accumulation region HC to be generated in this manner can be regarded as a p+ layer (p column) at the time of an operation of the power MOSFET. The hole accumulation region HC overlaps with the body region BD and the drift layer DL. Note that in a region where the substrate region SBR having high concentration of the n type impurities and the hole accumulation region HC overlap with each other, the concentration of the hole accumulation region HC decreases, or the hole accumulation region HC is not formed.

A thickness of the hole accumulation region HC in the X direction can be controlled by forming the fixed charge layer FC with a desired thickness. Namely, by controlling the thickness of the fixed charge layer FC, the amount of accumulated holes can be controlled. In order to stabilize a silicon interface (that is, reduce leakage), the insulating film IF1 is formed between the fixed charge layer FC and the semiconductor substrate SB. The insulating film IF1 can be formed by a deposition method such as an oxidation method or a CVD (Chemical Vapor Deposition) method, for example. The fixed charge layer FC can be formed by a deposition method such as a CVD method after the insulating film IF1 is formed, for example. The insulating film IF2 is a TEOS (Tetra Ethyl Ortho Silicate) film that is formed by a CVD method, for example, after the fixed charge layer FC is formed.

The interlayer insulating film IL is arranged on the upper surface of the semiconductor substrate SB. The interlayer insulating film IL has a through hole TH. The interlayer insulating film IL is a silicon oxide film, for example. The source electrode SE is arranged on the upper surface of the semiconductor substrate SB. The source electrode SE is formed in the through hole TH and on the interlayer insulating film IL. The source electrode SE is electrically connected to the source region SR and the p type body region BD through a contact hole arranged in the through hole TH. The source electrode SE is an Al (aluminum) film, for example.

The drain electrode DE is arranged on the lower surface of the semiconductor substrate SB (the substrate region SBR). The drain electrode DE is electrically connected to the drift layer DL via the substrate region SBR. The power MOSFET is a MOSFET that has a vertical structure. The drain electrode DE is an aluminum (Al) film, for example.

The power MOSFET according to the present embodiment has a super junction structure in which the insulator columns ICLM (p column) each provided with the fixed charge layer FC that causes the hole accumulation region HC to be generated and the n type drift layers DL (n column) are arranged alternately in the X direction.

<Operation of Semiconductor Device>

In the power MOSFET according to the present embodiment having the super junction structure, the n type drift layers DL (n column) and the insulator columns ICLM (p column) each provided with the hole accumulation region HC are arranged alternately in the drift layer DL. Here, when a voltage is applied between the source and the drain at the time of OFF of the power MOSFET, depletion layers spread in the X direction from a bonding surface between the drift layer DL and the hole accumulation region HC. By integrating these depletion layers with each other, a depletion layer having a depth of the groove is formed. Therefore, it is possible to secure the withstand pressure even though the impurity concentration of the drift layer DL is set to relatively high. This makes it possible to reduce an ON resistance.

<Effects of Semiconductor Device>

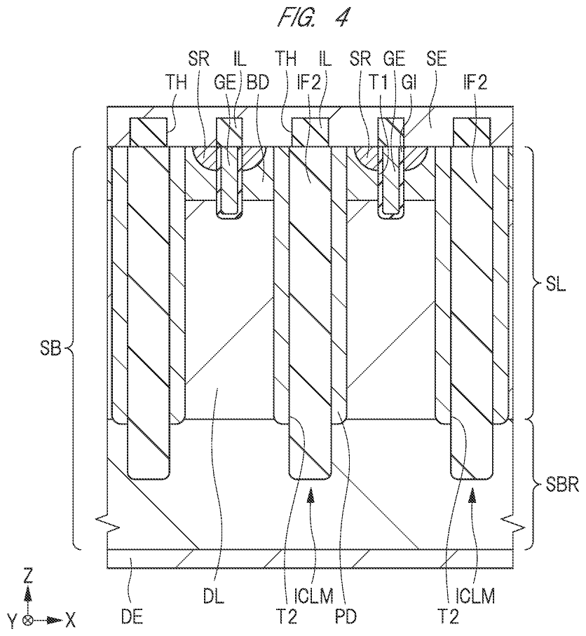

FIG. 4 illustrates a sectional view of a semiconductor device according to a comparative example. The semiconductor device according to the comparative example is a power MOSFET having a super junction structure in which a p column having a p+ type diffusion layer PD formed by an ion implantation method and an n column made by a drift layer DL adjacent to the p column are provided. The semiconductor device according to the comparative example is different from the power MOSFET described with reference to FIG. 1 in that the inside of a trench T2 is completely embedded by an insulating film IF2 and no fixed charge layer FC is formed. Further, the semiconductor device according to the comparative example is also different from the power MOSFET described with reference to FIG. 1 in that the inside of the trench T2 is completely embedded by only the insulating film IF2 and no fixed charge layer FC is formed. An insulator column ICLM that is the p column includes the insulating film IF2 in the trench T2 and the diffusion layer PD formed on a side surface of the trench T2. Other structure than these is the same as those of the power MOSFET described with reference to FIG. 1.

The trench T2 according to the comparative example illustrated in FIG. 4 appears to have a vertical side surface along a Z direction, but in actual, a side surface of the trench T2 is formed diagonally with respect to the Z direction, and has a trench angle. In a step of forming diffusion layers PD, p-type ions are implanted into a surface of a semiconductor substrate SB with a tilt angle of, for example, 1 degree to 10 degrees in the Z direction by an oblique ion implantation method. As a result, a p+ type diffusion layer PD is formed in the semiconductor substrate SB in contact with the side surface of the trench T2.

Here, it is conceivable that the trench angle on the side surface of each of a plurality of the trenches T2 may vary in each of the trenches T2, in each chip, or in each wafer. In that case, there arises a problem that an amount of injected impurities in the diffusion layer PD varies due to variation in manufacturing of the trench T2. If the amount of injected impurities in the diffusion layer PD varies, characteristics (withstand pressure) of the power MOSFET vary. Therefore, reliability of the semiconductor device decreases.

On the other hand, in the present embodiment, the p+ type diffusion layer PD is not formed by the ion implantation method, but the fixed charge layer FC, which is the high-k film, is formed in the trench T2. Here, by forming the fixed charge layer FC, the hole accumulation region HC is formed as the p+ layer in the semiconductor layer SL in the vicinity of the side surface of the trench T2.

In the present embodiment, the insulating film IF1 is formed in the trench T2 by the oxidation method or the deposition method, and then the fixed charge layer FC is formed by the deposition method. Namely, it is possible to form the fixed charge layer FC having a fixed film thickness at a fixed distance from the side surface of the trench T2. Here, by form each of the insulating film IF1 and the fixed charge layer FC with the fixed film thickness in the trench T2 and embedding the region other than the insulating films in the trench T2 with the insulating film IF2, it is possible to form the hole accumulation region HC stably.

For this reason, regardless of the variation in the trench angle of the trench T2, it is possible to stabilize the thickness and the hole accumulation amount of the hole accumulation region HC formed in the vicinity of the side surface of each of the trenches T2. Therefore, even though the trench angle of the trench T2 varies, it is possible to improve reliability of the semiconductor device because it is possible to prevent variation in the characteristics (withstand pressure) of the power MOSFET from occurring.

### Second Embodiment

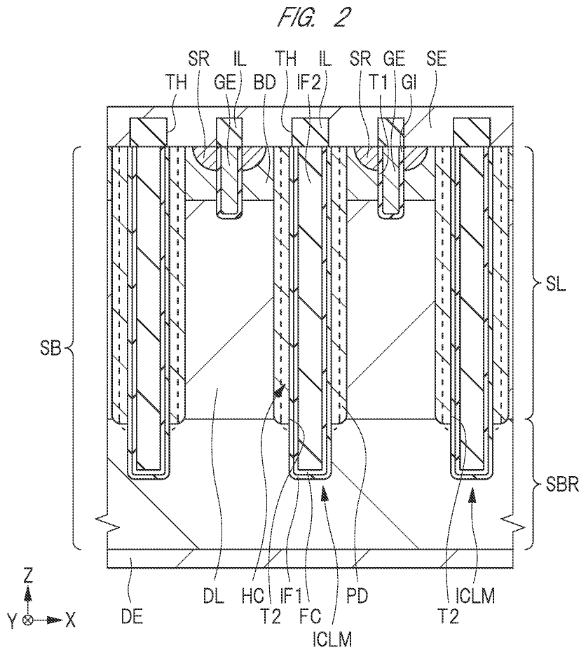

FIG. 2 illustrates a sectional view of a power MOSFET according to a second embodiment. A structure of the power MOSFET according to the present embodiment is different from that according to the first embodiment in that a diffusion layer PD, which is a p type semiconductor region, is formed on a side surface of a trench T2.

An insulator column ICLM, which is a p column, includes a diffusion layer PD formed on the side surface of the trench T2 in a semiconductor substrate SB in addition to an insulating film IF1 in the trench T2, a fixed charge layer FC, and an insulating film IF2. The diffusion layer PD is formed in the semiconductor substrate SB at a predetermined depth from the side surface of the trench T2 in an X direction. Here, a width of the diffusion layer PD in the X direction is larger than a width of a hole accumulation region HC in the X direction. Here, a case where the diffusion layer PD is in contact with the side surface of the trench T2 will be described. However, the diffusion layer PD may be formed in the semiconductor substrate SB at a position separated from the side surface of the trench T2 by a fixed distance. Namely, the diffusion layer PD may be formed in the semiconductor substrate SB at a predetermined distance from the side surface of the trench T2.

The diffusion layer PD is formed by ion implantation after formation of the trench T2 and before formation of the insulating film IF1. Namely, in a step of forming the diffusion layer PD, by an oblique ion implantation method, p-type ions are implanted into a surface of the semiconductor substrate SB with a tilt angle of 1 degree to 10 degrees in a Z direction, for example. As a result, the p+ type diffusion layer PD is formed in the semiconductor substrate SB in contact with the side surface of the trench T2.

In a case where elements constituting the p column are only the insulating films IF1 and IF2 and the fixed charge layer FC in the trench T2 and a hole accumulation amount in the p column is insufficient, by forming the p type diffusion layer PD as in the present embodiment, it is possible to supplement the hole accumulation amount. In the first embodiment, with reference to the comparative example illustrated in FIG. 4, it has been described that variation in characteristics occurs in the power MOSFET having the diffusion layer PD varies. On the other hand, in the present embodiment, the insulator column ICLM has the fixed charge layer FC. Thus, the amount of injected impurities in the diffusion layer PD may be smaller than that in the diffusion layer PD according to the comparative example. Therefore, according to the present embodiment, it is possible to suppress the variation in the amount of injected impurities in the diffusion layer PD due to the variation in a trench angle, and it is possible to secure the hole accumulation amount in the p column. Therefore, even though the trench angle of the trench T2 varies, it is possible to prevent the variation in the characteristics (withstand pressure) of the power MOSFET from occurring. This makes it possible to improve reliability of the semiconductor device.

### Third Embodiment

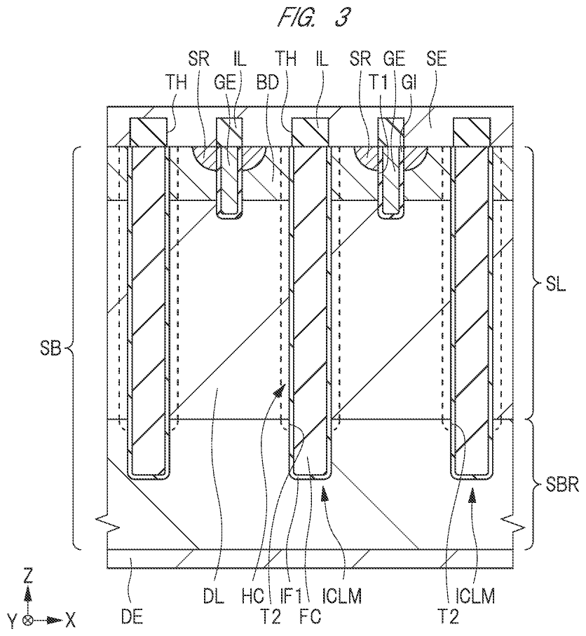

FIG. 3 illustrates a sectional view of a power MOSFET according to a third embodiment. A structure of the power MOSFET according to the present embodiment is different from that according to the first embodiment in that an insulating film IF2 is not formed in each of trenches T2 and a fixed charge layer FC is completely embedded in the trench T2 via an insulating film IF1.

A width and a hole accumulation amount of a hole accumulation region HC formed beside the trench T2 can be controlled by a thickness of the fixed charge layer FC in the trench T2. In the present embodiment, by filling the trench T2 with the fixed charge layer FC via the insulating film IF1, a desired width and a desired hole accumulation amount of the hole accumulation region HC can be obtained. Therefore, regardless of the variation in the trench angle, it is possible to form the hole accumulation region HC stably. This makes it possible to stabilize the withstand pressure of the power MOSFET. Therefore, it is possible to improve reliability of the semiconductor device.

As described above, the invention made by the inventors of the present application has been described specifically on the basis of the embodiment. However, the present invention is not limited to the embodiment described above, and it goes without saying that the present invention may be modified into various forms without departing from the substance thereof.

For example, the second embodiment and the third embodiment may be combined with each other.

What is claimed is:

1. A semiconductor device comprising:
a semiconductor substrate having a first principal surface and a second principal surface opposite to the first principal surface;
an n type drift layer arranged in the semiconductor substrate;
a p type body region arranged on the first principal surface side of the drift layer in the semiconductor substrate;
an n type source region arranged on the first principal surface side of the body region in the semiconductor substrate;
a gate insulating film arranged on a portion of the body region sandwiched between the drift layer and the source region;
a gate electrode facing the portion of the body region so as to interpose the gate insulating film;
a plurality of grooves formed from the first principal surface to an intermediate depth of the semiconductor substrate, a side surface of the groove being in contact with the body region and the drift layer; and
a fixed charge layer formed in the groove via a first insulating film,
wherein the plurality of grooves is arranged side by side in a direction along the first principal surface of the groove.

2. The semiconductor device according to claim 1,
wherein a material constituting the fixed charge layer is at least one kind selected from a group consisting of hafnium oxide, hafnium oxynitride, yttrium oxide, and aluminum oxide.

3. The semiconductor device according to claim 1,
wherein a hole accumulation region is formed on the side surface of the groove adjacent to the fixed charge layer.

4. The semiconductor device according to claim 1,
wherein a p type diffusion layer is formed in a space in the semiconductor substrate from the side surface of the groove to a predetermined distance.

5. The semiconductor device according to claim 1,
wherein the fixed charge layer is formed in the groove via the first insulating film.

6. The semiconductor device according to claim 1,
wherein the groove is filled with a second insulating film via the fixed charge layer.

7. The semiconductor device according to claim 1,
wherein the groove is filled with the fixed charge layer via the first insulating film.
